(19) United States
(12) Patent Application Publication
(10) Pub. No.: US 2014/0346476 A1
(43) Pub. Date: Nov. 27, 2014

(54) OLED DISPLAY PANEL AND THE PACKAGING METHOD THEREOF, DISPLAY DEVICE

(71) Applicant: BOE TECHNOLOGY GROUP CO., LTD., Beijing (CN)

(72) Inventor: Jikai Yao, Beijing (CN)

(21) Appl. No.: 14/241,955

(22) PCT Filed: Aug. 14, 2013
(86) PCT No.: PCT/CN2013/081460

§ 371 Date: Feb. 28, 2014

(30) Foreign Application Priority Data
May 24, 2013 (CN) 201310199269.X

(51) Int. Cl. H01L 51/52; H01L 51/56

(52) U.S. Cl. CPC H01L 51/5259; H01L 51/5246; H01L 51/56
USPC 257/40; 438/26

(57) ABSTRACT

An OLED display panel comprises an OLED substrate, an encapsulation cover plate arranged opposite to the OLED substrate, and an adhesive film provided between the OLED substrate and the encapsulation cover plate, and further comprises a moistureproof material capable of absorbing moisture; the moistureproof material is provided in the adhesive film. The embodiments of the present invention eliminate the volume increase of the OLED display panel. A method for packaging the OLED display panel and a display device comprising the OLED display panel are also provided.

### TECHNICAL FIELD

Embodiments of the present invention relate to an OLED display panel and a packaging method thereof, a display device.

### BACKGROUND

An OLED (Organic Light-Emitting Diode) display belongs to a new type of display device. Comparing with a liquid crystal display, an OLED display is advantageous in self-illumination, rapid response speed, wide viewing-angle and so on, and the OLED display can realize flexible display, transparent display and 3D display, thus obtaining instant development and becoming popularity.

As shown in FIG. 1, current OLED display panels are commonly packaged in a glue package method. The process of packaging in a glue package method is as below: forming an adhesive film 104 on the OLED substrate 101 (i.e., a substrate formed with OLED structure), arranging the OLED substrate 101 oppositely to an encapsulation cover plate 103, and then completing the package. Due to the moisture in air may permeate through the adhesive film 104 and thus generate disadvantageous influence on the service life of the organic luminescent materials in the OLED structure 102, a moisture resistant layer 105 completely covering the OLED structure is further provided between the OLED substrate 101 and the adhesive film 104 when the OLED display panel is packaged with glue, so as to eliminate the disadvantageous influence of the moisture in air upon the service life of the organic luminescent materials in the OLED structure 102. Because the moisture resistant layer 105 has a certain thickness and a certain width, the moisture resistant layer 105 increases the volume of the OLED display panel.

Generally, in order to avoid the disadvantageous influence of the moisture in air upon the organic luminescent materials in the OLED structure, current OLED display panels commonly comprise a moisture resistant layer having a certain thickness and a certain width, thus increasing the volume of the OLED display panel.

### SUMMARY

Embodiments of the present invention provides an OLED display panel and a packaging method thereof, a display device, which are used to solve the problem of volume increase of the OLED display panel due to provision of a moisture resistant layer.

One embodiment of the present invention provides an OLED display panel, comprising an OLED substrate, an encapsulation cover plate arranged opposite to the OLED substrate, an adhesive film provided between the OLED substrate and the encapsulation cover plate, and a moistureproof material capable of absorbing moisture; the moistureproof material is arranged in the adhesive film.

Another embodiment of the present invention provides a display device comprising the OLED display panel.

Still another embodiment of the present invention provides a method for packaging the OLED display panel, comprising: forming an adhesive film on an OLED substrate and/or an encapsulation cover plate, wherein the adhesive film comprises a moistureproof material capable of absorbing moisture; and arranging the OLED substrate opposite to the encapsulation cover plate, thus completing the packaging.

### BRIEF DESCRIPTION OF THE DRAWINGS

In order to illustrate the technical solution of the embodiment of the present invention more clearly, a simply introduction about the drawings of the embodiments will be made in the following, and obviously, the drawings described later relate to only some embodiments of the present invention, rather than limitation to the present invention.

FIG. 1 is a structural schematic view of the OLED display panel in prior art;

FIG. 2 is a structural schematic view of the OLED display panel according to an embodiment of the present invention;

FIG. 3 is a side view of the OLED display panel of an embodiment of the present invention;

FIG. 4 is a top view of the OLED display panel of an embodiment of the present invention;

FIGS. 5A-5D are side views of the OLED display panel of an embodiment of the present invention;

FIG. 6 is a side view of the OLED display panel of an embodiment of the present invention;

FIG. 7 is a structural schematic view of the adhesive film of an embodiment of the present invention; and

FIG. 8 is a flow chart schematic view illustrating the method for packaging the OLED display panel according to an embodiment of the present invention.

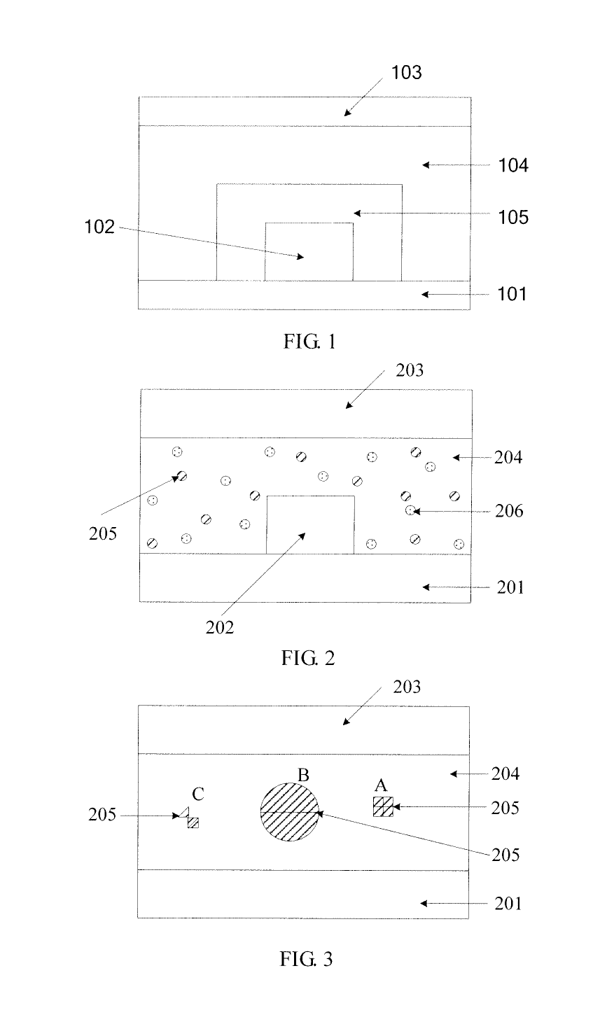

### DETAILED DESCRIPTION

To make clearer the object, technical solutions and advantages of the embodiments of the present invention, a clear and full description of the technical solution of the embodiment of the present invention will be made with reference to the accompanying drawings of the embodiment of the present invention. Obviously, the described embodiments are merely part of the embodiments of the present invention, but not all the embodiments. Based on the described embodiments of the present invention, all the other embodiments obtained by the ordinary skilled in this art, without any creative labor, fall into the protective scope of the present invention.

An OLED display panel according to an embodiment of the present invention comprises an OLED substrate, an encapsulation cover plate arranged opposite to the OLED substrate, and an adhesive film provided between the OLED substrate and the encapsulation cover plate; and the display panel further comprises a moistureproof material capable of absorbing moisture, and the moistureproof material is provided in the adhesive film. Since the moistureproof material capable of absorbing moisture is arranged in the adhesive film, the moistureproof material contained in the adhesive film absorbs the moisture in air upon the moisture in air being permeating through the adhesive film. In this way, the disadvantageous or adverse effect of the moisture in air upon the organic luminescent material in the OLED structure can be avoided. Accordingly, the OLED display panel according to the embodiment of the present invention does not require a moisture resistant layer between the OLED substrate and the adhesive film any more, thus avoiding the volume increase of the OLED display panel.

To be specified, the OLED substrate of the embodiment of the present invention is a substrate formed with an OLED structure.

As shown in FIG. 2, an OLED display panel provided by an embodiment of the present invention comprises an OLED substrate 201 formed with the OLED structure 202, an encapsulation cover plate 203 arranged opposite to the OLED substrate 201, an adhesive film 204 located between the OLED substrate 201 and the encapsulation cover plate 203, and a moistureproof material 205 capable of absorbing moisture. The moistureproof material 205 is arranged in the adhesive film 204, for example, dispersed in the adhesive film 204.

For example, the OLED display panel provided by the embodiment of the present invention comprises at least one piece of the moistureproof material 205.

The more pieces of moistureproof material 205 the OLED display panel contains, the better effect of the OLED display panel will have to absorb moisture. The moistureproof material 205 can be any substance capable of absorbing moisture, for instance, desiccant (dying agent) or substance comprising desiccant.

For example, the moistureproof material 205 can be chemisorption desiccant or physisorption desiccant, such as solid desiccant, liquid desiccant, transparent desiccant, nontransparent desiccant, black desiccant, and so on.

For example, the moistureproof material 205 may be a granular desiccant, such as silica-gel desiccant.

Where the moistureproof material 205 is silica-gel desiccant, no secondary chemical pollution is brought when the moistureproof material 205 absorbs moisture.

For example, the moistureproof material 205 may be of any shapes, such as regular shapes or irregular shapes.

For example, when the shape of the moistureproof material 205 is of a regular shape, the regular shape comprises one or more of cylinder, cone and sphere.

For example, the size of the moistureproof material 205 may be elected according to specific requirements, however it's necessary to ensure that the moistureproof material 205 is provided within the adhesive film 204.

Any implementation ways in which the moistureproof material 205 is provided in the adhesive film 204 are applicable to the embodiment of the present invention. For example, the moistureproof material 205 may be blended within the adhesive film 204, the moistureproof material 205 may be inserted into the adhesive film 204, or the adhesive film 204 encases the moistureproof material 205, etc.

An implementation way in which the moistureproof material 205 of the embodiment of the present invention is provided in the adhesive film 204 will be described by taking the situation in which the moistureproof material 205 is a granular desiccant or articles comprising granular desiccant as an example. Other implementation ways are similar to these ways, and therefore the description thereof is omitted here.

1. The moistureproof material 205 is a granular desiccant

Preferably, the moistureproof material 205 is, for example, blended within the adhesive film 204. The moistureproof material 205 may be evenly blended within the adhesive film 204, and may also be unevenly blended within the adhesive film 204.

In the case where the moistureproof material 205 is evenly blended into the adhesive film 204, the moistureproof material 205 blended within the adhesive film 204 is evenly distributed; in the case where the moistureproof material 205 is unevenly blended within the adhesive film 204, the moistureproof material 205 blended within the adhesive film 204 is aggregated in at least one area of the adhesive film 204.

In the case where the moistureproof material 205 is unevenly blended within the adhesive film 204 and thus several pieces of moistureproof material 205 aggregate together; the region in which the moistureproof material aggregates may be of a regular shape, and also may have an irregular shape.

For example, the region in which the moistureproof material aggregates has a circular shape and/or a polygon shape.

As shown in FIG. 2, for example, the moistureproof material 205 is essentially evenly blended within the adhesive film 204.

As shown in FIG. 3, the region in which the moistureproof material aggregates may be of a regular shape or an irregular shape. The region A in FIG. 3 is a region in which four pieces of the moistureproof material 205 aggregate together, and is of a regular square in shape; the region B in FIG. 3 is a region in which two pieces of the moistureproof material 205 aggregate together, and is of a regular circular in shape; the region C in FIG. 3 is a region in which three pieces of the moistureproof material 205 aggregate together, and has an irregular shape.

For example, the moistureproof material 205 may be blended within the entire adhesive film 204, and may also be blended within part of the adhesive film 204.

For example, the moistureproof material 205 is blended within the adhesive film 204 around the OLED structure 202, and the projections of the moistureproof material 205 blended within the adhesive film 204 upon the OLED substrate 201 assume a quadrilateral distribution.

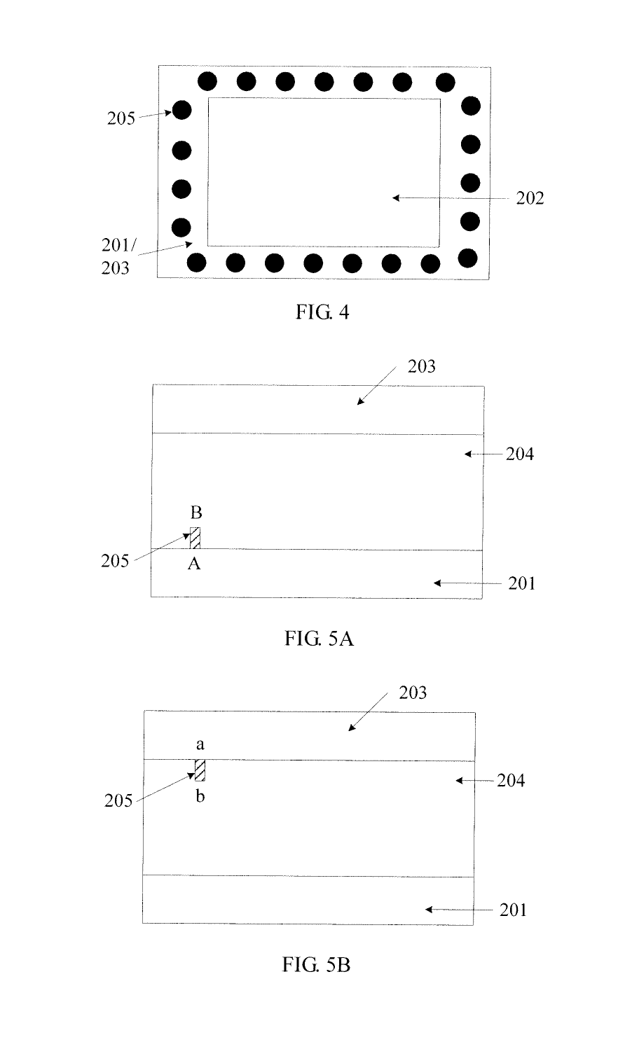

For example, as shown in FIG. 4, the projections of the moistureproof material 205 blended within the adhesive film 204 upon the OLED substrate 201 assume a rectangular distribution.

For example, as for one piece of the moistureproof material 205 contained by the OLED display panel, any implementation way in which the moistureproof material 205 is blended within the adhesive film 204 applies to the embodiment of the present invention, and several typical situations will be listed and described in the following.

(1). the moistureproof material 205 is blended within the adhesive film 204 and contacts with the OLED substrate 201.

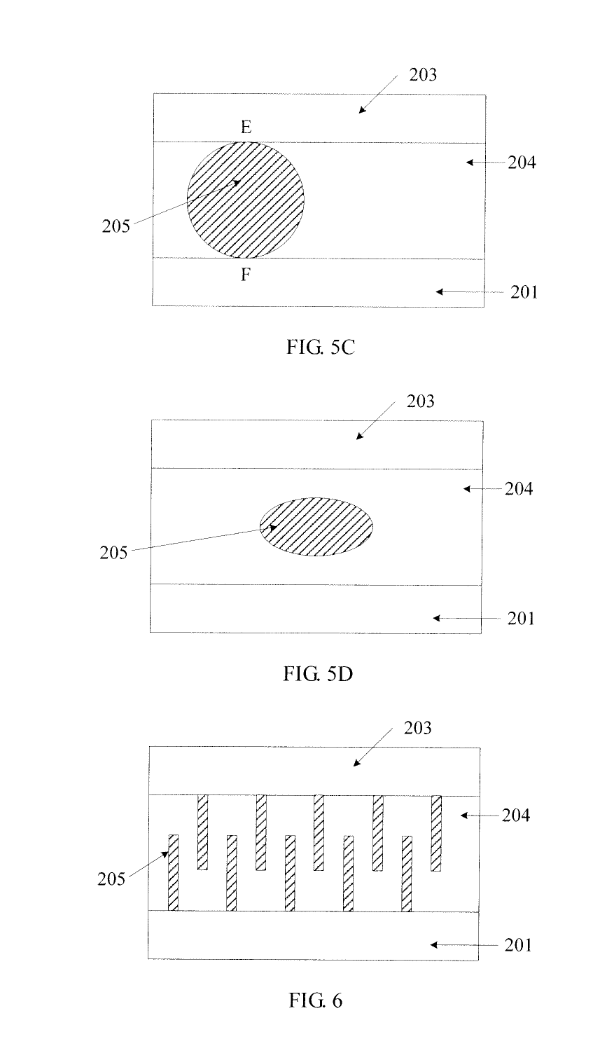

For example, as shown in FIG. 5A, the moistureproof material 205 is blended within the adhesive film 204, and an end A of the moistureproof material 205 contacts with the OLED substrate 201, and an end B of the moistureproof material 205 does not contact with the encapsulation cover plate 203.

(2). The moistureproof material 205 is blended within the adhesive film 204 and contacts with the encapsulation cover plate 203.

For example, as shown in FIG. 5B, the moistureproof material 205 is blended within the adhesive film 204, and an end a of the moistureproof material 205 contacts with the OLED substrate 201, and an end b of the moistureproof material 205 does not contact with the encapsulation cover plate 203.

(3). The moistureproof material 205 is blended within the adhesive film 204 and contacts with the OLED substrate 201 and the encapsulation cover plate 203.

For example, as shown in FIG. 5C, the moistureproof material 205 is blended within the adhesive film 204, and contacts with both the OLED substrate 201 and the encapsulation cover plate 203. The moistureproof material 205 contacts with the encapsulation cover plate 203 at a point E, and contacts with the OLED substrate 201 at a point F.

(4). The moistureproof material 205 is blended within the adhesive film 204, and does not contact with the OLED substrate 201 nor the encapsulation cover plate 203 (that is, the moistureproof material 205 does not contact with the OLED substrate 201, and does not contact with the encapsulation cover plate 203 also).

For example, as shown in FIG. 5D, the moistureproof material 205 is blended within the adhesive film 204, and does a not contact with the OLED substrate 201 nor the encapsulation cover plate 203.

2. The moistureproof material 205 comprises articles of granular desiccant.

For example, the moistureproof material 205 is a first attachment obtained through an etching process on a mixture comprising a granular desiccant and a photo-sensitive liquid material.

For example, the moistureproof material 205 is adhered to the OLED substrate 201 and/or the encapsulation cover plate 203, and the adhesive film 204 encases the moistureproof material 205.

For example, as shown in FIG. 6, part of the moistureproof material 205 is adhered to the OLED substrate 201, and other part of the moistureproof material 205 is adhered to the encapsulation cover plate 203, and the adhesive film 204 encases the moistureproof material 205.

Because the mixture of the granular desiccant and the photo-sensitive liquid material can be fixed onto the OLED substrate 201 and/or the encapsulation cover plate 203, the first attachment obtained through the etching process on the mixture comprising the granular desiccant and the photo-sensitive liquid material can be adhered to the OLED substrate 201 and/or the encapsulation cover plate 203 as well.

For example, any photo-sensitive liquid material in related art, such as photosensitive resin, can be applied to the embodiment of the present invention.

The shape of the moistureproof material 205 may be connected with the shape of the masking plate used in the etching process. For example, the moistureproof material and/or the anti-oxidation material may be of a regular shape or an irregular shape; preferably, the moistureproof material and/or the anti-oxidation material may be of a cylindrical shape and/or a spherical shape.

In the case where the moistureproof material 205 has a cylindrical shape and/or a spherical shape, the region in which the moistureproof material 205 contacts with the moisture in air become large, the OLED display panel thus has a better effect for absorbing moisture.

In the case where the moistureproof material 205 is adhered to the OLED substrate 201 and the encapsulation cover plate 203, the OLED display panel has a better effect for absorbing the moisture.

For example, the OLED display panel provided by the embodiment of the present invention may further comprise an anti-oxidation material 206 for reducing oxygen gas; the anti-oxidation material 206 is arranged within the adhesive film 204.

The anti-oxidation material 206 comprised in the OLED display panel can reduce oxygen gas, and thus eliminate the disadvantageous influence of the oxygen gas in the air on the organic luminescent material in the OLED structure 202.

For example, the OLED display panel provided by the embodiment of the present invention may comprise at least one anti-oxidation material 206.

The more anti-oxidation material 206 the OLED display panel contains, the better effect of the OLED display panel will have to absorb moisture.

For example, the anti-oxidation material 206 can be any articles capable of reducing oxygen gas, such as a reductant or articles comprising the reductant. For example, the anti-oxidation material 206 can be a chemical reductant or a physics reductant such as solid reductant.

For example, the anti-oxidation material 206 are granular reductant (such as, Fe (Ferrum) particles), or the second attachment obtained through an etching process on a mixture comprising the granular reductant and the photo-sensitive liquid material.

For example, the implementation ways of the shape and size of the anti-oxidation material 206 are similar to those of the moistureproof material 205; the detailed description thereof is omitted here.

For example, the implementation ways of anti-oxidation material 206 being provided within the adhesive film 204 are similar to that of the moistureproof material 205 being provided within the adhesive film 204; detailed description thereof is omitted here.

For example, the moistureproof material 205 and/or the anti-oxidation material 206 blended within the adhesive film 204 are evenly distributed; or the moistureproof material and/or anti-oxidation material, which are (is) blended within the adhesive film, are aggregated in at least one region of the adhesive film 204.

For example, the region in which the moistureproof material 205 and/or the anti-oxidation material 206 aggregate has a circular shape and/or a polygon shape. For example, the projections of the moistureproof material 205 and/or the anti-oxidation material 206 blended within the adhesive film 204 upon the OLED substrate 201 assumes an quadrangle distribution.

For example, the moistureproof material 205 and/or the anti-oxidation material 206 are (is) adhered to the OLED substrate 201 and/or the encapsulation cover plate 203, and the adhesive film 204 encases the moistureproof material 205 and the anti-oxidation material 206.

For example, the moistureproof material 205 and/or the anti-oxidation material 206 may be of a cylindrical shape and/or a spherical shape.

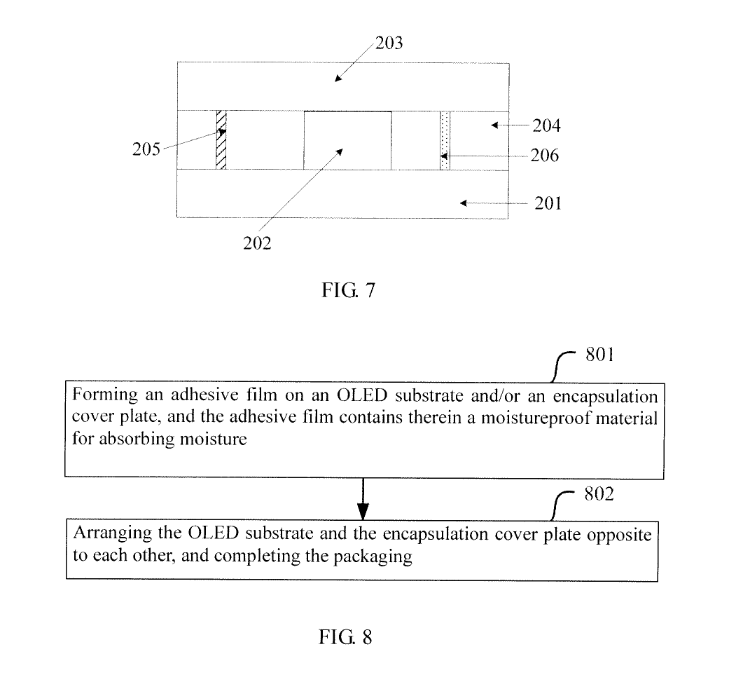

For example, as shown in FIG. 7, the adhesive film 204 is provided in an area of the OLED substrate 201, which area is not covered by the OLED structure 202, and the thickness of the adhesive film 204 equals to that of the OLED structure 202.

For example, when the adhesive film 204 is provided in the area of the OLED substrate 201, which area is not covered by the OLED structure 202, and the thickness of the adhesive film 204 equals to that of the OLED structure 202, it's possible to reduce the thickness of the OLED display panel and thus reduce the volume of the OLED display panel.

For example, the display device of the embodiment of the present invention comprises the above described OLED display panel.

As shown in FIG. 8, the method for packaging the OLED display panel according to an embodiment of the present invention comprises the following steps:

Step 801: forming an adhesive film on an OLED substrate and/or an encapsulation cover plate, wherein the adhesive film contains therein a moistureproof material for absorbing moisture;

Step 802: arranging the OLED substrate and the encapsulation cover plate opposite to each other, and completing the packaging.

For example, the adhesive film may further comprise therein anti-oxidation material for the reduction of oxygen.

For example, the moistureproof material is a granular desiccant, and the anti-oxidation material is a granular reductant. The adhesive film comprising the moistureproof material and the anti-oxidation material can be formed on the OLED substrate and/or the encapsulation cover plate, for example, the moistureproof material and the anti-oxidation material may be blended within the adhesive film, and the adhesive film blended with the moistureproof material and the anti-oxidation material is provided on the OLED substrate and/or the encapsulation cover plate.

For example, the moistureproof material and the anti-oxidation material may be blended into the adhesive film by the way for blending two or more articles together in prior art, for example; the moistureproof material and the anti-oxidation material may be added into the material for the adhesive film, and then the material of the adhesive film added with the moistureproof material and the anti-oxidation material is stirred, thereby resulting in the blending of the moistureproof material and the anti-oxidation material into the adhesive film.

For example, after blending the moistureproof material and the anti-oxidation material into the adhesive film and before the adhesive film blended with the moistureproof material and the anti-oxidation material are provided on the OLED substrate and/or the encapsulation cover plate, the mixture comprising the moistureproof material, the anti-oxidation material, and the material for the adhesive film may be subjected to a debubbling process.

The debubbling process of the mixture comprising the moistureproof material, the anti-oxidation material and the material for the adhesive film can improve the compactness degree of the moistureproof material and the anti-oxidation material with the adhesive film.

For example, the adhesive film blended with the moistureproof material and the anti-oxidation material may be provided on the OLED substrate and/or the encapsulation cover plate in a way for arranging the adhesive film on the OLED substrate and/or the encapsulation cover plate in prior art, and for example a coating method may be employed to provide the adhesive film blended with the moistureproof material and the anti-oxidation material on the OLED substrate and/or the encapsulation cover plate.

For example, the moistureproof material is a first attachment obtained through an etching process on the mixture comprising the granular desiccant and the photo-sensitive liquid material, and the anti-oxidation material is the second attachment obtained through an etching process on the mixture comprising the granular reductant and the photo-sensitive liquid material, an adhesive film containing the moistureproof material and the anti-oxidation material is formed on the OLED substrate and/or the encapsulation cover plate, for example, the OLED substrate and/or the encapsulation cover plate may be formed with moistureproof material and the anti-oxidation material adhered thereto, and the adhesive film encases the moistureproof material and the anti-oxidation material.

For example, the OLED substrate and/or the encapsulation cover plate are (is) formed with moistureproof material and the anti-oxidation material adhered thereto, for example, the moistureproof material and the anti-oxidation material may be blended with a photo-sensitive liquid material, and the mixture of the moistureproof material, the anti-oxidation material, and the photo-sensitive liquid material is provided on the OLED substrate and/or the encapsulation cover plate; with a photolithography technology, the OLED substrate and/or the encapsulation cover plate are (is) formed with the moistureproof material and the anti-oxidation material adhered thereto.

For example, the shape of the moistureproof material and the anti-oxidation material adhered to the OLED substrate and/or the encapsulation cover plate is connected with the masking plate used in the photolithography technology.

The adhesive film is made to encase the moistureproof material and the anti-oxidation material, and for example the adhesive film may be provided on the OLED substrate and/or the encapsulation cover plate adhered thereon with the moistureproof material and the anti-oxidation material.

Because the adhesive film is in colloid, after the adhesive film is provided on the OLED substrate and/or the encapsulation cover plate adhered thereon with the moistureproof material and the anti-oxidation material, the adhesive film encases the moistureproof material and the anti-oxidation material, and therefore an adhesive film, containing the moistureproof material and the anti-oxidation material, is formed on the OLED substrate and/or the encapsulation cover plate.

Although advantageous embodiments of the present invention have described in the above, it's possible for the skilled person in this art to make additional alternation and modification once knowing the essential inventive concept. Therefore, the accompanying claims intend to be interpreted as comprising preferable embodiments and all alternations and modifications falling into the scope of the present invention.

1. An OLED display panel comprising an OLED substrate, an encapsulation cover plate arranged opposite to the OLED substrate, an adhesive film provided between the OLED substrate and the encapsulation cover plate, and a moistureproof material capable of absorbing moisture, wherein the moistureproof material is provided in the adhesive film.

2. The OLED display panel according to claim 1, wherein the moistureproof material is a granular desiccant.

3. The OLED display panel according to claim 1, further comprising an anti-oxidation material for reduction of oxygen gas; wherein the anti-oxidation material is provided in the adhesive film.

4. The OLED display panel according to claim 3, wherein the anti-oxidation material is a granular reductant.

5. The OLED display panel according to claim 3, wherein the moistureproof material and/or anti-oxidation material, which are blended within the adhesive film, are evenly distributed; or
the moistureproof material and/or anti-oxidation material, which are blended within the adhesive film, aggregate in at least one region of the adhesive film.

6. The OLED display panel according to claim 5, wherein a region in which the moistureproof material and/or the anti-oxidation material aggregate is of a circular shape and/or a polygonal shape.

7. The OLED display panel according to claim 3, wherein projections of the moistureproof material and/or the anti-oxidation material blended within the adhesive film upon the OLED substrate assume a quadrangle distribution.

8. The OLED display panel according to claim 3, wherein the moistureproof material is a first attachment obtained through an etching process on a mixture comprising a granular desiccant and a photo-sensitive liquid material.

9. The OLED display panel according to claim 4, wherein the anti-oxidation material is the second attachment obtained through an etching process on a mixture comprising the granular reductant and a photo-sensitive liquid material.

10. The OLED display panel according to claim 3, wherein the moistureproof material and/or the anti-oxidation material are adhered to the OLED substrate and/or the encapsulation cover plate, and the adhesive film encases the moistureproof material and the anti-oxidation material.

11. The OLED display panel according to claim 3, wherein the moistureproof material and/or the anti-oxidation material are of a cylindrical shape and/or a spherical shape.

12. The OLED display panel according to claim 1, wherein the adhesive film is arranged in an area of the OLED substrate, which area is not covered by the OLED structure, and a thickness of the adhesive film is equal to a thickness of the OLED structure.

13. A display device comprising the OLED display panel according to claim 1.

14. A method for packaging the OLED display panel comprising:
forming an adhesive film on an OLED substrate and/or an encapsulation cover plate, wherein the adhesive film comprises a moistureproof material capable of absorbing moisture therein; and
arranging the OLED substrate opposite to the encapsulation cover plate, thus completing the packaging.

15. The method according to claim 14, wherein the adhesive film further comprises therein an anti-oxidation material for reduction of oxygen gas.

16. The method according to claim 15, wherein the moistureproof material is a granular desiccant, the anti-oxidation material is a granular reductant, and forming of the adhesive film comprising a moistureproof material and an anti-oxidation material on the OLED substrate and/or the encapsulation cover plate comprises:
blending the moistureproof material and the anti-oxidation material into the adhesive film, and providing the adhesive film blended with the moistureproof material and the anti-oxidation material onto the OLED substrate and/or the encapsulation cover plate.

17. The method according to claim 16, wherein the moistureproof material is a first attachment obtained through an etching process on a mixture comprising a granular desiccant and a photo-sensitive liquid material, the anti-oxidation material is a second attachment obtained through an etching process on a mixture comprising a granular reductant and a photo-sensitive liquid material, and forming of the adhesive film comprising the moistureproof material and the anti-oxidation material onto the OLED substrate and/or the encapsulation cover plate comprises:
the moistureproof material and/or the anti-oxidation material are adhered to the OLED substrate and/or the encapsulation cover plate, and the moistureproof material and the anti-oxidation material are encased with the adhesive film.
